(19) United States
(12) Patent Application Publication
(10) Pub. No.: US 2009/0032189 A1
(43) Pub. Date: Feb. 5, 2009

(54) SUBSTRATE PROCESSING APPARATUS HAVING A SENSING UNIT

(76) Inventor: Won Ki JEONG, Seongnam-si (KR)

Correspondence Address: KED & ASSOCIATES, LLP, P.O. Box 221200, Chantilly, VA, 20153-1200, US

(21) Appl. No.: 12/144,677

(22) Filed: Jun. 24, 2008

(30) Foreign Application Priority Data
Aug. 1, 2007 (KR) 10-2007-0077462

(51) Int. Cl. H01L 21/306

(52) U.S. Cl. 156/345.24

(57) ABSTRACT

A substrate processing apparatus includes a chamber having a process space, a support plate in the chamber to support a substrate, a shower head above the support plate and having a body with an opened lower part, and a spray plate connected to the lower part of the body to supply source gas above the support plate. The apparatus further includes a sensing unit having a sensor and an elastic member. One end of the sensor is in contact with an upper surface of the spray plate. The elastic member provides elastic force to the sensor in a direction toward the spray plate.

### BACKGROUND

1. Field

One or more embodiments described herein relate to processing substrates including semiconductor substrates.

2. Background

Semiconductor devices are used in forming integrated circuits, flat panel displays, and other electronic products. These devices are usually made by alternatively depositing layers on a substrate with intervening etching steps. The layers include, for example, borophosphosilicate glass (BPSG), polysilicon and one or more metals patterned using a photoresist.

Semiconductor devices have traditionally been formed in a chamber. In order to obtain desired results, process parameters of the chamber must be precisely controlled. Currently, there is a need to improve the control of these parameters in order to produce a more reliable product a less cost.

### BRIEF DESCRIPTION OF THE DRAWINGS

FIG. 1 is a diagram showing one embodiment of a substrate processing apparatus.

FIG. 2 is a magnified view of a sensing unit of FIG. 1.

FIG. 3 is a diagram showing an elastic force applied to a pressure surface of a housing of FIG. 2.

### DETAILED DESCRIPTION

In order to produce a semiconductor product of a desired quality, certain process parameters must be precisely controlled. One parameter is temperature. In a process that uses plasma, it is especially important to control temperature because etching quality is very sensitive to temperature changes during processing.

In order to control temperature, one technique involves use of a support plate and shower head in a chamber of a plasma processing apparatus. In operation, a substrate is placed on the support plate and the shower head supplies source gas above the plate. The shower head includes a spray plate which faces the support plate. During processing, the temperature of the spray plate may increase as a result of exposure to plasma that discharges heat energy.

In accordance with one or more embodiments described herein, the temperature of the spray plate is controlled in order to control the temperature of the plasma processing apparatus. This involves exactly measuring the temperature of the spray plate during processing.

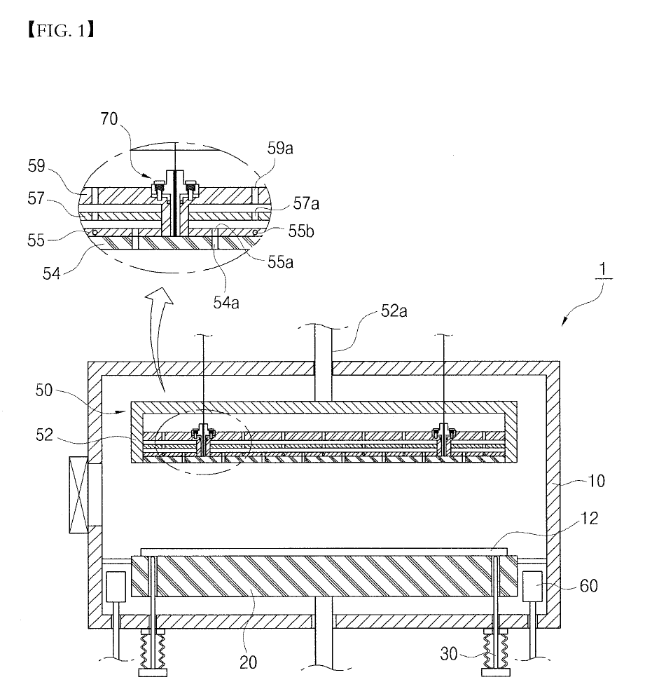

FIG. 1 shows one embodiment of a substrate processing apparatus that includes a chamber 10, a support plate 20, an elevation member 30, a shower head 50, and an exhaust unit 60. The chamber provides a process space where processes are to be performed on a substrate. The process space is sealed and the exhaust unit keeps an interior of the chamber in a vacuum state during processing by discharging gas in the chamber.

The support plate 20 is provided at a lower part of the chamber. During processing, a substrate 12 is placed on the support plate and etched by plasma. The support plate may be an electrostatic chuck (ESC). Elevation members 30 are arranged at an edge of the support plate for moving the substrate up and down as necessary.

The shower head 50 is provided above support plate 20 to supply source gas above the support plate. The shower head generates plasma from the source gas and includes a body 52 and a spray plate 54 connected to a lower part of the body. The body has a shape having a lower part that is opened. The spray plate is combined with the open lower part of the body, and the body is provided at an upper part of the support plate 20 by a support shaft 52a.

The shower head further includes a cooling plate 55, a diffusion plate 57, and an upper electrode 59. The cooling plate is adjacent an upper surface of the spray plate 54 and controls a temperature of the spray plate using refrigerant that flows through a refrigerant path 55b. The diffusion plate is above the cooling plate and diffuses the source gas toward the spray plate. The upper electrode 59 is above the diffusion plate 57 and 59 and may be connected to an additional RF generator.

The upper electrode 59 forms an electrical field over support plate 20, while the support plate is grounded, and also generates plasma from the source gas supplied above the support plate. The source gas may be supplied into body 52 from an external source. The source gas is supplied above support plate 20 through a hole 59a that passes through upper electrode 59, diffusion hole 57a of the diffusion plate 57, hole 55a of the cooling plate 55, and a spray hole 54a of the spray plate 54. A sensing unit 70 is provided on the upper electrode.

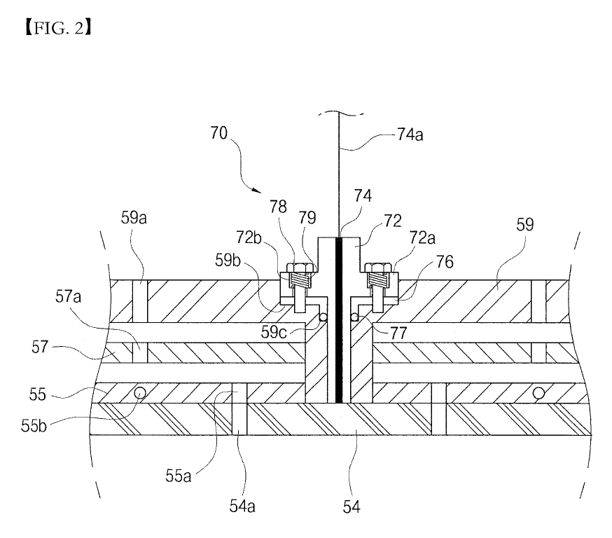

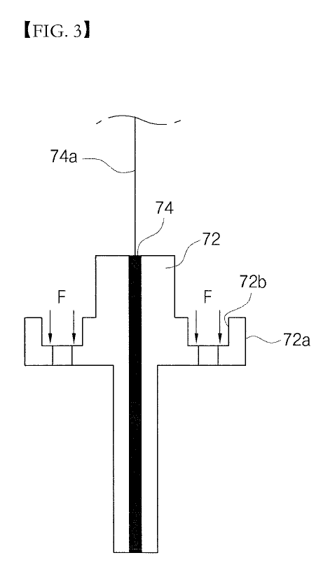

FIG. 2 shows a larger view of sensing unit 70 of FIG. 1, and FIG. 3 shows elastic force applied to a pressure surface of a housing 72 of FIG. 2.

The sensing unit 70 includes a housing 72, a sensor 74, and a fastening unit 78. The sensor is installed in the housing and a lower end of the sensor is in contact with an upper surface of spray plate 54. The upper end thereof is connected to an additional controller (not shown) through a wire 74a. The sensor senses a temperature of the spray plate and a controller controls the temperature of the spray plate based on the temperature detected by the sensor.

The sensor may include a resistance temperature detector (RTD) that provides stable output within a wide temperature range and that measures temperature exactly within a narrow temperature range. The detector may detect temperature based on the relationship that electrical resistance of a metal conductor varies with changes in temperature, e.g., by measuring changes in resistance of the metal.

The housing 72 includes a flange part 72a around the sensor 74. A plurality of fastening holes 72b is formed on the flange part, and fastening members 78 pass through respective ones of the fastening holes 72b and are fixed to upper electrode 59. The fastening members may have diameters larger than the fastening holes and may project out of flange part 72a. The flange part is fixed to upper electrode 59 by the fastening members in an elevated position. Similar to the lower end of the sensor 74, a lower end of the housing 72 is in contact with an upper surface of the spray plate. The sensor contacts to the upper surface of the spray plate 54 by sensor 74 as a result of the sensor installed in housing 72.

An elastic member 79 is provided on each fastening member. Preferably, one end of the elastic member contacts a pressure surface of a fastening hole 72b that is parallel with the upper surface of upper electrode 59. The other end of the elastic member is in contact with a head of the fastening member. The elastic member, for example, may be compression spring.

As shown in FIG. 3, each elastic member provides a downward elastic force to the pressure surface of a respective one of the fastening holes. Thus, the lower end of housing 72 can be maintained in contact with the upper surface of the spray plate at all times. Similarly, the lower end of sensor 74 can be kept in contact with the upper surface of the spray plate 54 at all times.

The upper electrode 59 includes a seating surface 59b facing the flange part 72a. A sealing pad 76 may be provided between the seating surface and flange part 72a, and a sealing surface 59c may be provided inside seating surface 59b. The sealing surface is located below the seating surface 59b, and an O-ring 77 is provided between sealing surface 59c and sealing pad 76 to maintain an airtight connection.

Sensor 74 may be in contact with the upper surface of spray plate 54 based, at least in part, on the elastic force provided by elastic member 79. A constant state of contact between the sensor and spray plate may be maintained based on this elastic force. By maintaining a constant state of contact, the temperature of the spray plate may be measured with greater precision and control of the temperature inside of the process chamber 10 may be exactly controlled.

The embodiments described herein therefore provide a sensing unit that can exactly measure and therefore control a temperature of the spray plate, to thereby improve the substrate manufacturing process and produce a more reliable product.

In accordance with one or more of these embodiments, a substrate processing apparatus is provided to include a chamber providing process space where processes are performed on a substrate; a support plate provided in the chamber, where the substrate is placed on the support plate; a shower head, provided above the support plate, having a body whose lower part is opened and a spray plate connected to the lower part of the body to supply source gas above the support plate; and a sensing unit having a sensor and an elastic member, where one end of the sensor is contacted to an upper surface of the spray plate and the elastic member provides elastic force to the sensor in a direction toward the spray plate.

The shower head may further include a fixing plate provided inside the body and above the spray plate. The sensing unit may further include a housing for installing the sensor, a fastening unit for installing the housing on the fixing plate. The elastic member may provide elastic force to the housing.

The housing may include a fastening hole that the fastening unit passes through. One end of the elastic member may be contacted to a pressure surface of the fastening hole and the other end may be connected to a head of the fastening unit having a diameter larger than the fastening hole.

The housing may include a flange part provided around the sensor, where the flange part has a fastening hole that the fastening unit passes through. The fixing plate may include a seating surface where the flange part is seated. The sensing unit may further include a sealing pad provided between the flange part and seating surface to keep airtightness. The fixing plate may further include a sealing surface located inside the seating surface, where the sealing surface is located to be lower than the seating surface. The sensing unit may further include a sealing member provided between the sealing pad and sealing surface to keep airtightness. The fixing plate may be an upper electrode that generates plasma with the support plate by using the source gas supplied from the shower head.

The shower head may further include a diffusion plate provided between the fixing plate and spray plate, and a cooling plate provided between the diffusion plate and spray plate to control a temperature of the spray plate.

According to one or more additional embodiments, a sensing unit is provided to include a sensor whose one end is contacted to a measured surface of a measured object; and an elastic member providing elastic force to the sensor in a direction toward the measured surface. The sensing unit may further include a housing for installing the sensor, a fastening unit for installing the housing on the fixing plate that is provided near the measured surface. The elastic member may provide elastic force to the housing.

The foregoing embodiments therefore provide a sensing unit and substrate processing apparatus which can produce at least the following effects. The sensor can be maintained in constant contact with the measured surface of the object. As a result, a more reliable measurement of process temperature may be obtained and thus the temperature of the chamber can be precisely controlled.

While the foregoing embodiments have been described as measuring temperature, other embodiments may include a sensing unit that senses process parameters other than temperature, e.g., pressure.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A substrate processing apparatus, comprising:
a chamber including a process space;
a support plate in the chamber to support a substrate;
a shower head, above the support plate, having a body with a lower part that is opened and a spray plate connected to the lower part of the body to supply source gas above the support plate; and
a sensing unit having a sensor and an elastic member, wherein one end of the sensor is in contact with an upper surface of the spray plate and wherein the elastic member provides elastic force to the sensor in a direction toward the spray plate.

2. The apparatus of claim 1, wherein:
the shower head includes a fixing plate inside the body and above the spray plate,
the sensing unit includes a housing for installing the sensor and a fastening member for coupling the housing to the fixing plate, and
the elastic member provides elastic force to the housing.

3. The apparatus of claim 2, wherein the housing includes a fastening hole that the fastening member passes through, and wherein one end of the elastic member is in contact with a pressure surface of the fastening member and the other end of the elastic member is connected to a head of the fastening member having a diameter larger than the fastening hole.

4. The apparatus of claim 2, wherein the housing includes a flange part around the sensor, the flange part having a fastening hole that the fastening member passes through, and wherein:
the fixing plate has a seating surface where the flange part is seated, and
the sensing unit has a sealing pad between the flange part and seating surface to maintain an airtight connection.

5. The apparatus of claim 4, wherein the fixing plate includes a sealing surface inside the seating surface, the sealing surface lower than the seating surface, and
wherein the sensing unit includes a sealing member between the sealing pad and sealing surface to maintain an airtight connection.

6. The apparatus of claim 5, wherein the fixing plate is an upper electrode that generates plasma with the support plate using the source gas supplied from the shower head.

7. The apparatus of claim 6, wherein the shower head includes:
a diffusion plate between the fixing plate and spray plate, and
a cooling plate between the diffusion plate and spray plate to control a temperature of the spray plate.

8. A sensing unit, comprising:
a temperature sensor object; and
an elastic member providing elastic force to the sensor in a direction toward a surface of an object whose temperature is to be measured.

9. The sensing unit of claim 8, further comprising:
a housing for installing the sensor; and
a fastening member for installing the housing on the fixing plate that is provided near the surface where the elastic member provides elastic force to the housing.

10. The sensing unit of claim 8, wherein the housing comprises:
a fastening hole that the fastening member passes through,
wherein one end of the elastic member is in contact with a pressure surface of the fastening hole and the other end of the elastic member is connected to the fastening member having a diameter larger than the fastening hole.
